(19) United States
(12) Patent Application Publication
(10) Pub. No.: US 2008/0100323 A1
(43) Pub. Date: May 1, 2008

(54) LOW COST, HIGH PIN COUNT, WAFER SORT AUTOMATED TEST EQUIPMENT (ATE) DEVICE UNDER TEST (DUT) INTERFACE FOR TESTING ELECTRONIC DEVICES IN HIGH PARALLELISM

(75) Inventor: Romi O. Mayder, San Jose, CA (US)

Correspondence Address: SCHNECK & SCHNECK, P.O. BOX 2-E, SAN JOSE, CA, 95109-0005, US

(73) Assignee: SILICON TEST SYSTEMS, INC., San Jose, CA (US)

(21) Appl. No.: 11/685,857

(22) Filed: Mar. 14, 2007

Related U.S. Application Data
(60) Provisional application No. 60/862,883, filed on Oct. 25, 2006.

(51) Int. Cl. G01R 31/02

(52) U.S. Cl. 324/761

(57) ABSTRACT

An interference device to communicate electrical signals from a probe card used to test electronic circuits. The interface device includes at least one interposer configured to electrically couple to the probe card and a plurality of mechanical springs mechanically coupled to the at least one interposer. Each of the plurality of mechanical springs is removably arranged such that one or more of the plurality of mechanical springs may be removed. A flexible circuit is electrically coupled to the plurality of mechanical springs. The flexible circuit is further configured to mechanically couple to the at least one interposer.

### CROSS-REFERENCE TO RELATED APPLICATION

This application claims priority from U.S. Provisional Patent Application Ser. No. 60/862,883 entitled “Low Cost, High Pin Count, Wafer Sort Automated Test Equipment (ATE) Device under Test (DUT) Interface for Testing Electronic Devices in High Parallelism” filed Oct. 25, 2006 which is hereby incorporated by reference in its entirety.

### TECHNICAL FIELD

The present invention is related generally to electronic device testing. More specifically, the present invention is related to device-under-test (DUT) interface for mating to a probe card used in testing electronic devices.

### BACKGROUND

Complexity levels of electronic device testing vary tremendously, from simple manual low-volume/low-complexity testing performed with perhaps an oscilloscope and voltmeter, to personal computer-based medium-scale testing, to large-scale/high-complexity automated test equipment (ATE). Manual and personal computer-based testing are typically applied to testing discrete devices, specific components of an integrated circuit, or portions of a printed circuit board. In contrast, ATE testing is used to test functionality of a plurality of complex integrated circuits such as memory circuits or hundreds of dice on a wafer prior to sawing and packaging.

When testing ICs on a wafer, it is cost effective to test as many devices as possible in parallel, thus reducing the test time per wafer. Test system controllers have evolved to increase the total number of channels and hence the number of devices that can be tested in parallel. However, a test system controller with increased test channels is typically a significant cost factor for a test system, as is a probe card with complex routing lines used to accommodate multiple parallel test channels. Thus, an overall probe card architecture that allows increased test parallelism without requiring increased test system controller channels and without increased probe card routing complexity and cost is desirable.

FIG. 1 shows a block diagram of an automated test system 100. The test system 100 includes a test system controller 101, a test head 105, and a test prober 107. The test system controller 101 is frequently a microprocessor-based computer and is electrically connected to the test head 105 by a communication cable 103. The test prober 107 includes a stage 109 on which a semiconductor wafer 111 may be mounted, and a probe card 113 for testing DUTs on the semiconductor wafer 111. The stage 109 is movable to contact the wafer 111 with a plurality of test probes 115 on the probe card 113. The probe card 113 communicates with the test head 105 through a plurality of channel communications cables 117.

In operation, the test system controller 101 generates test data which are transmitted through the communication cable 103 to the test head 105. The test head in turn transmits the test data to the probe card 113 through the plurality of communication cables 117. The probe card then uses these data to probe DUTs (not shown explicitly) on the wafer 111 through the plurality of test probes 115. Test results are then provided from the DUTs on the wafer 111 back through the probe card 113 to the test head 105 for transmission back to the test system controller 101. Once testing is completed and known-good dice are identified, the wafer is 111 diced.

Test data provided from the test system controller 101 are divided into individual test channels provided through the communications cable 103 and separated in the test head 105 so that each channel is carried to a separate one of the plurality of test probes 115. Channels from the test head 105 are linked by the channel communications cables 117 to the probe card 113. The probe card 113 then links each channel to a separate one of the plurality of test probes 115.

With reference to FIG. 2 and continued reference to FIG. 1, a cross-sectional view of components contained within the probe card 113 indicate routing of mechanical and electrical couplings between the wafer 111 and the test head 105. The probe card 113 provides both electrical pathways and mechanical support for the plurality of test probes 115 that will directly contact the wafer 111. Electrical pathways on the probe card 113 are provided through a printed circuit board (PCB) 201, an interposer 203, and a space transformer 205. Test data from the test head 105 are provided through the channel communications cables 117 typically connected around the periphery of the PCB 201. A plurality of channel transmission lines 207 distribute signals from a plurality of electrical interconnects 209 (only two electrical interconnects are shown for clarity) mounted on the PCB 201 to match the routing pitch of pads on the space transformer 205. The interposer 203 includes a substrate 211 with a plurality of spring probe electrical contacts 213 disposed on both sides. The interposer 203 electrically connects individual pads on the PCB 201 to pads forming a land grid array (LGA, not shown explicitly) on the space transformer 205. A plurality of electrical traces 215 in a substrate 217 of the space transformer 205 distribute or “space transform” connections from the LGA to the plurality of test probes 115, configured in an array. The space transformer substrate 217 is typically constructed from either multi-layered ceramic or organic-based laminates. The space transformer substrate 217 with embedded circuitry, probes, and LGA is referred to as a probe head.

Mechanical support for the electrical components is provided by a back plate 219, a probe head bracket 221, a probe head stiffener frame 223, a plurality of leaf springs 225, and leveling pins 227. The frame 223 surrounds the probe head and maintains a close tolerance to the bracket 221 such that lateral motion is limited.

The leveling pins 227 complete the mechanical support for the electrical elements and provide for leveling of the space transformer 205. The leveling pins 227 are adjusted so that brass spheres 229 provide a point contact with the space transformer 205. The spheres 229 contact outside the periphery of the LGA of the space transformer 205 to maintain electrical isolation from electrical components. Motion of the leveling pins 227 is opposed by the plurality of leaf springs 225 so that the spheres 229 are kept in contact with the space transformer 205.

The complexity of the automated test system 100 an the probe card 113 demonstrates an inherent potential problem in contemporary ATE systems. For example, a critical component of the probe card 113 is the plurality of electrical interconnects 209. All generated test data and resulting DUT data are funneled through the plurality of electrical interconnects 209. In contemporary ATE systems, the plurality of electrical interconnects 209 are designed using pogo pins, coaxial cables, zero insertion force clamp assemblies, or other expensive interconnect technologies. Pogo pins suffer from reliability problems associated with repeatable contact resistance. Coaxial cables are large in diameter and can not be contained in a small volume of space. Zero insertion force clamp assemblies are mechanically complex and mechanics associated with operations of the assembly occupy valuable real estate which could otherwise be used for more interconnects.

Therefore, what is needed is a simple, economical, and robust means of interacting bidirectional electrical signals between the test head and probe card. Such an interface should have individually replaceable contact points with a sufficient z-dimension deformational stroke to allow for slight misalignment errors or irregularities in the surface of the probe head. Further, the interface should reduce a deflection in the probe card by minimizing an applied load to compress the contact points. The reduced deflection allows a large contactor array to be mounted on the probe card, further increasing parallelism.

### SUMMARY OF THE INVENTION

In an exemplary embodiment, the present invention is an interface device to communicate electrical signals from a probe card used to test electronic circuits. The interface device includes at least one interposer configured to electrically couple to the probe card and a plurality of mechanical springs mechanically coupled to the at least one interposer. Each of the plurality of mechanical springs is removably arranged such that one or more of the plurality of mechanical springs may be removed. A flexible circuit is electrically coupled to the plurality of mechanical springs. The flexible circuit is further configured to mechanically couple to the at least one interposer.

In another exemplary embodiment, the present invention is an interface device to communicate electrical signals from a probe card used to test electronic circuits. The interface device includes a plurality of interposers configured to be electrically coupled to the probe card and a plurality of mechanical springs mechanically coupled to each of the plurality of interposers. Each of the plurality of mechanical springs is at least partially formed from an electrically conductive material. Each of the plurality of mechanical springs further has a stroke of at least 100 μm and is removably arranged such that one or more of the plurality of mechanical springs may be removed for replacement. A plurality of flexible circuits is configured to be mechanically coupled to select ones of the plurality of interposers and electrically couple to select ones of the plurality of mechanical springs.

In another exemplary embodiment, the present invention is an interposer for communicating electrical signals from a probe card used to test electronic circuits. The interposer includes a plurality of mechanical springs mechanically coupled to the interposer and arranged in a matrix. Each of the plurality of mechanical springs is at least partially formed from an electrically conductive material. Each of the plurality of mechanical springs further has a stroke of at least 100 μm and is removably arranged such that one or more of the plurality of mechanical springs may be removed for replacement. At least one flexible circuit is configured to be mechanically coupled to the interposer and electrically coupled to select ones of the plurality of mechanical springs.

### BRIEF DESCRIPTION OF THE DRAWINGS

FIG. 1 is a block diagram of an ATE system of the prior art.

FIG. 2 is a cross-sectional view of a prior art probe card contained in the system of FIG. 1.

FIG. 3 is a simplified block diagram of an exemplary embodiment of the present invention.

FIG. 4 is a perspective view of an exemplary probe card of the present invention.

FIG. 5 is a plan view of an exemplary interposer of the present invention used to interface electrical signals to the probe card of FIG. 4 through a plurality of mechanical springs.

FIG. 6 is an elevation view showing a specific embodiment with optional daughter cards mounting on the probe card of FIG. 4.

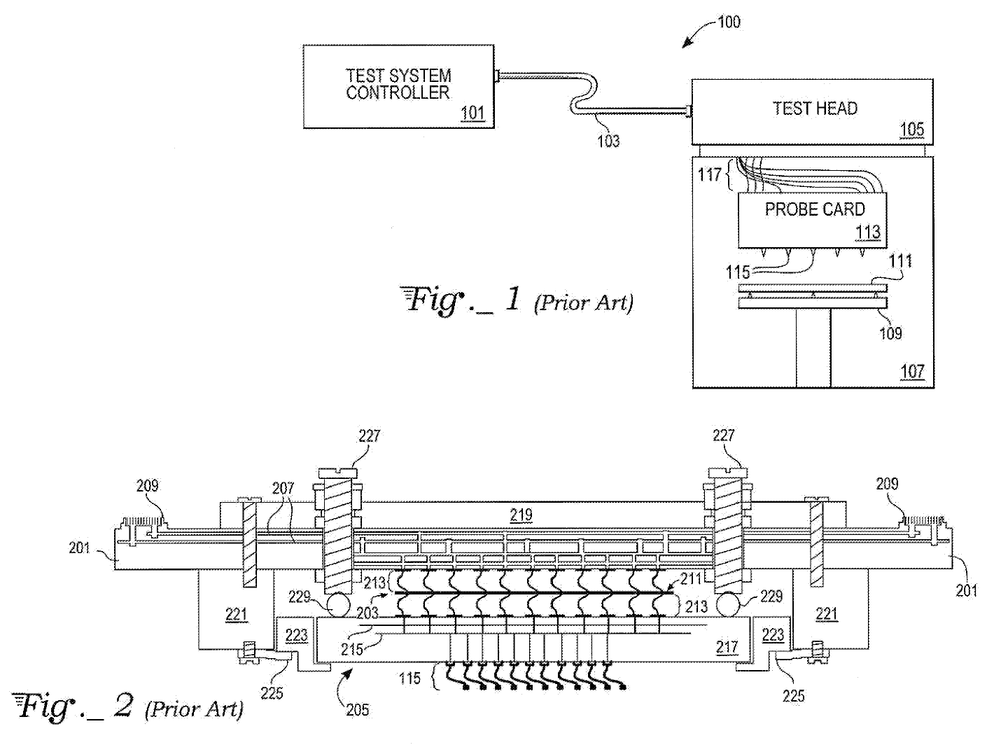

### DETAILED DESCRIPTION

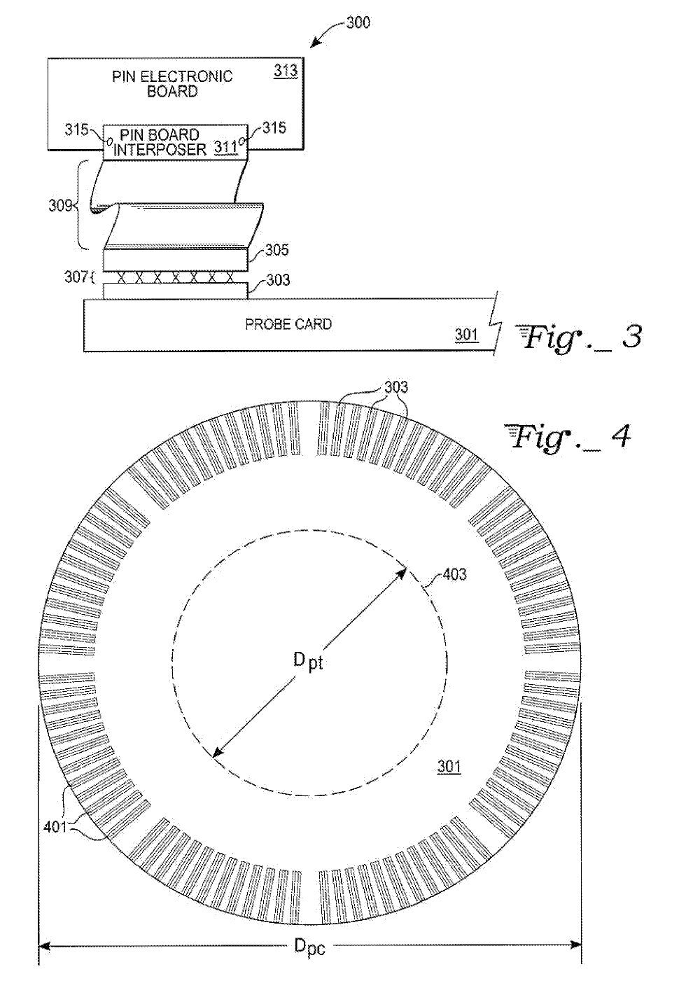

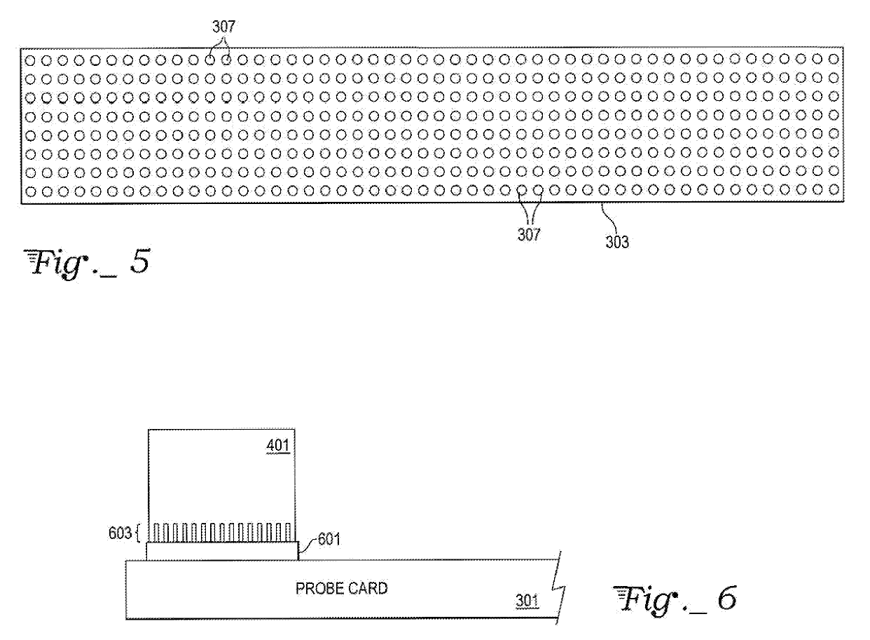

With reference to FIG. 3, a portion of a DUT interface 300 includes a probe card 301, a probe card interposer 303, and a mechanical backing plate 305 electrically and mechanically connected to a flex circuit 309. Electrical communication is provide between the mechanical backing plate 305 and the probe card interposer 303 through a plurality of mechanical springs 307. Ideally, each of the plurality of mechanical springs 307 should be designed to be individually field-replaceable with a sufficient stroke (i.e., greater than 100 μm) to allow for any misalignment error or surface irregularities between the probe card interposer 303 and the mechanical backing plate 305. Additionally, the plurality of mechanical springs 307 may be mounted on either the probe card interposer 303, the mechanical backing plate 305, or both (i.e., a spring-to-spring contact). No connectors are required to be mounted directly on the probe card 301. Each of the plurality of mechanical springs may take various forms known in the art and include various compressional spring types such as volute, helical, coil, cantilever, or leaf springs. Both macro-mechanical and micro-mechanical methods for producing various forms of spring elements are also known in the art. The probe card interposer is described in more detail with reference to FIG. 5, below.

The flex circuit 309 may either be a simple flat cable interconnect or it may be a flexible electronic interconnect containing active and passive device circuitry. Flex circuits of the latter type involve fabricating various device types on plastic, such as a polyethyleneterephthalate (PET) substrate. PET substrates are commonly employed in lightweight circuit applications, such as a cellular telephone or personal data assistant (PDA). Such circuits are known in the art and electronic devices are formed on, for example, a PET substrate deposited with silicon dioxide and polysilicon followed by an excimer laser annealing (ELA) anneal step. In a simple case, flexible electronics can be made using similar components used on rigid printed circuit boards.

The flex circuit 309 is electrically and mechanically connected to a pin electronic board 313 through a pin board interposer 311. The pin board interposer 311 is fastened to the pin electronic board 313 by, for example, mechanical fasteners 315. The mechanical fasteners 315 may be screws, rivets, wire bails, or other fastening means known in the art.

The flex circuit 309 may be routed to the probe card 301 and bent by, for example, 90 degrees to lay substantially horizontal to a plane of the probe card 301. The probe card interposer 303 may be placed on top of the flex circuit 309. The probe card interposer 303 may be floating on top of mechanical springs to allow greater compliance along the vertical axis. The probe card 301 is clamped against or is otherwise attached to the mechanical backing plate 305, which applies a load required to compress the probe card interposer 303. The probe card interposer 303 may have its own set of springs to allow compression over an interface area of the probe card due to any surface irregularities or warpage of the probe card 301 caused by load and temperature. Hence, mechanical springs may be used to allow each of a plurality of the probe card interposers 303 to float individually.

In FIG. 4, a top perspective view of the probe card 301 showing an exemplary arrangement includes a plurality of probe card interposers 303 and a plurality of optional daughter board edge connectors 401. Mounting of the daughter board edge connectors 401 is described in more detail with reference to FIG. 6, below. A probe tip 403 is located on the bottom side of the probe card 301. Due to the relatively small size of each of the plurality of probe card interposers 303, a larger probe tip 403 array may be used to contact more devices on a substrate (e.g., a wafer) in parallel. In a specific exemplary embodiment, there are 64 probe card interposers 303 DUT interface and an equal number of daughter board edge connectors 401 interspersed with the probe card interposers 303. Other arrangements and numbers could readily be envisioned by a skilled artisan based on layouts disclosed herein. Continuing with the specific exemplary embodiment, a diameter, D_{pc}, of the probe card 301 is 510 mm and a diameter, Dₚₜ, of the probe tip is 400 mm. Each of these dimensions may be changed based on relative sizes needed for substrates probed (e.g., probing a next generation silicon wafer may require a 450 mm probe tip 403).

In FIG. 5, a detailed plan view of the spring contact side of the probe card interposer 303 includes a plurality of mechanical springs 307. In a specific exemplary embodiment, the plurality of mechanical springs is laid out in an 8 column by 52 row matrix (thus, there are 416 mechanical springs 307). The matrix has a 1 mm by 1.25 mm pitch respectively for the columns and rows. Consequently, an overall size of the probe card interposer 303 is 9 mm×66.25 mm.

Depending upon spring type chosen, each of the plurality of mechanical springs 307 requires a force of only about 30 N (Newtons) or a total force of 12,480 N per each of the probe card interposers 303. Thus, the total force on a probe card is significantly less than required under the prior art, allowing more interconnects to be used per probe card with less overall deflection. One field-replaceable spring type that may be used with the present invention is employed in the InterCon cLGA® land grid array socket system (manufactured by Amphenol InterCon Systems, Inc., Harrisburg, Pa.). The Amphenol spring has a beryllium copper base with a gold over nickel-plated overcoat.

Significantly, the probe card interposer 303 allows for a much smaller footprint than the prior art since ZIF connectors or similar large and expensive connectors are not required. Thus, more interposers may be used, allowing a higher number of DUTs to be tested in parallel. The probe card interposer 303 may be mounted and remain permanently on the probe card 301 (FIG. 3). In the specific exemplary embodiment described above with 64 probe card interposers 303 per probe card 301 and 416 mechanical springs 307 per interposer, a total of 26,624 signal I/O, ground, power, and sense locations are available per DUT interface.

In FIG. 6, an elevation view of a portion of the probe card 301 indicates how each optional daughter card 601 may be mounted orthogonally through the use of the edge connector 401. Contacts on the edge connector 401 (not shown) electrically connect to a plurality of edge fingers 603 mounted on an edge of the daughter card 601. In a specific exemplary embodiment, the optional daughter card 601 is 6 mm thick with an area of 25 mm by 45 mm. Electronic devices may be mounted on one or both sides of the daughter card 601.

The probe card interposers 303 of the present invention provide significant advantages over the prior art. For example, due to the relatively small size of the probe card interposers 303, a large printed circuit board may be employed for improved routing of high frequency traces, more space is available for mechanically clamping the probe card to a DUT interface, and sufficient volume is present to mount a large number of orthogonal daughter boards on the tester side of the probe card. Daughter boards may be used for additional circuitry to aid in increasing the number of DUTs which can be tested in parallel. Also, a larger footprint is available for mounting electronic circuitry on the probe card and a high ratio of power supply contacts to signal contacts may be used. This high ratio is especially advantageous for testing low pin count devices (e.g., memory devices). Further, no mechanical tooling holes need be drilled in the area of the probe card where traces need to be routed thus both reducing a layer count of the probe card and increasing the number of the DUTs that can be tested in parallel.

In the foregoing specification, the present invention has been described with reference to specific embodiments thereof. It will, however, be evident to a skilled artisan that various modifications and changes can be made thereto without departing from the broader spirit and scope of the present invention as set forth in the appended claims. For example, various types of conducting materials may be used for the spring contacts. Alternatively, non-conductive spring materials may be employed which have a conductive outer layer, such as gold plating. Also, various fabrication technologies, such as micro-electromechanical systems (MEMS), may be employed in future generations of probe card interposers to manufacture spring contacts. These and various other embodiments and techniques are all within a scope of the present invention. The specification and drawings are, accordingly, to be regarded in an illustrative rather than a restrictive sense.

What is claimed is:

1. An interface device to communicate electrical signals from a probe card used to test electronic circuits, the interface device comprising:
at least one interposer configured to electrically couple to the probe card;
a plurality of mechanical springs mechanically coupled to the at least one interposer, each of the plurality of mechanical springs being removably arranged such that one or more of the plurality of mechanical springs may be removed; and
a flexible circuit electrically coupled to the plurality of mechanical springs, the flexible circuit further being configured to mechanically couple to the at least one interposer.

2. The interface device of claim 1 wherein each of the plurality of mechanical springs has a stroke of greater then 100 μm.

3. The interface device of claim 1 wherein each of the each of the plurality of mechanical springs is formed from an electrically conductive material.

4. The interface device of claim 1 wherein each of the plurality of mechanical springs is formed from a non-conductive material formed with an electrically conductive outer layer.

5. The interface device of claim 1 wherein the at least one interposer has the plurality of mechanical springs arranged in and 8 column by 52 row matrix.

6. The interface device of claim 5 wherein each of the plurality of springs has a pitch of 1 mm for the columns and 1.25 mm for the rows.

7. The interface device of claim 1 wherein each of the plurality of mechanical springs requires a contact force of about 30 Newtons for electrical communication.

8. The interface device of claim 1 further comprising an electrical coupling between the plurality of mechanical springs mechanically coupled to the at least one interposer to edge contacts located on each of a plurality of edge connectors arranged on the probe card, the plurality of edge connectors configured to allow daughter cards to be mounted orthogonally to a face of the probe card.

9. The interface device of claim 8 wherein 64 of the plurality of edge connectors are arranged on the probe card.

10. The interface device of claim 1 wherein 64 interposers are mechanically coupled to the probe card.

11. An interface device to communicate electrical signals from a probe card used to test electronic circuits, the interface device comprising:
a plurality of interposers configured to be electrically coupled to the probe card;
a plurality of mechanical springs mechanically coupled to each of the plurality of interposers, each of the plurality of mechanical springs being at least partially formed from an electrically conductive material, each of the plurality of mechanical springs further having a stroke of at least 100 μm and removably arranged such that one or more of the plurality of mechanical springs may be removed for replacement; and
a plurality of flexible circuits, each of the plurality of flexible circuits being configured to be mechanically coupled to select ones of the plurality of interposers and electrically coupled to select ones of the plurality of mechanical springs.

12. The interface device of claim 11 wherein the at least one interposer has the plurality of mechanical springs arranged in an 8 column by 52 row matrix.

13. The interface device of claim 12 wherein each of the plurality of springs has a pitch of 1 mm for the columns and 1.25 mm for the rows.

14. The interface device of claim 11 wherein each of the plurality of mechanical springs requires a contact force of about 30 Newtons for electrical communication.

15. The interface device of claim 11 further comprising an electrical coupling from the plurality of mechanical springs mechanically coupled to the at least one interposer to edge contacts on each of a plurality of edge connectors arranged on the probe card, the plurality of edge connectors configured to allow daughter cards to be mounted orthogonally to a face of the probe card.

16. The interface device of claim 15 wherein 64 of the plurality of edge connectors are arranged on the probe card.

17. The interface device of claim 11 wherein 64 interposers are mechanically coupled to the probe card.

18. An interposer for communicating electrical signals from a probe card used to test electronic circuits, the interposer comprising:
a plurality of mechanical springs mechanically coupled to the interposer and arranged in a matrix, each of the plurality of mechanical springs being at least partially formed from an electrically conductive material, each of the plurality of mechanical springs further having a stroke of at least 100 μm and removably arranged such that one or more of the plurality of mechanical springs may be removed for replacement; and
at least one flexible circuit, the at least one flexible circuit being configured to be mechanically coupled to the interposer and electrically coupled to select ones of the plurality of mechanical springs.

19. The interposer of claim 18 wherein the matrix is arranged to have 8 columns and 52 rows.

20. The interposer of claim 18 wherein each of the plurality of springs in the matrix has a pitch of 1 mm for the columns and 1.25 mm for the rows.

21. The interposer of claim 18 further comprising an electrical coupling from the plurality of mechanical springs to edge contacts on each of a plurality of edge connectors arranged on the probe card, the plurality of edge connectors configured to allow daughter cards to be mounted orthogonally to a face of the probe card.
